(19) United States
(12) Patent Application Publication
(10) Pub. No.: US 2008/0260946 A1
(43) Pub. Date: Oct. 23, 2008

(54) CLEAN METHOD FOR VAPOR DEPOSITION PROCESS

(75) Inventors: Hwee-Leong Tan, Singapore (SG); Cheng-Chung Lim, Singapore (SG); Jui-Lin Tang, Chiayi City (TW); Zhao-Jin Sun, Singapore (SG); Han-Chuan Fang, Singapore (SG)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/737,972

(22) Filed: Apr. 20, 2007

(51) Int. Cl. B08B 9/00; C23C 16/00

(52) U.S. Cl. 427/248.1; 134/22.1; 427/255.28

(57) ABSTRACT

A method for cleaning a reaction chamber having a pedestal and a carrier ring is provided. First, the pedestal and the carrier ring are cleaned with a high pressure gas. Next, the carrier ring is moved to leave the pedestal, and a low pressure gas is provided to clean the pedestal, the carrier ring, and an area lay between the pedestal and the carrier ring. Thereafter, a full flush is performed to clean the pedestal and the carrier ring.

### BACKGROUND OF THE INVENTION

1. Field of the Invention

The present invention relates to a clean method for a semiconductor process. More particularly, the present invention relates to a clean method for vapor deposition process.

2. Description of Related Art

Various vapor deposition processes are most commonly employed in material surface treatment worldwide. Currently, the vapor deposition is widely applied in industries, such as information, computers, semiconductors, and optical instruments, as well as the manufacturing of electronic components, optoelectronic equipments, solar cells, sensors, and so on. The vapor deposition can be classified into chemical vapor deposition (CVD) and physical vapor deposition (PVD) according to deposition modes.

CVD is the most widely utilized technique in the semiconductor industry for depositing various materials including insulating materials, metal materials, and metal alloy materials. In a CVD process, two or more kinds of gaseous raw materials are mainly guided into a reaction chamber to react with each other, so as to generate a new material that is then deposited to the surface of a material to be deposited.

During the vapor deposition, the film generated after the reaction is deposited on not only the material to be deposited, but also other members in the reaction chamber. Therefore, it is much important to clean the reaction chamber thoroughly.

Referring to FIG. 1, a schematic view of a vapor deposition technique commonly utilized in this field is shown. During the deposition, a substrate 450 is disposed on a pedestal 410 in a vapor deposition reaction chamber 400. The edge of the pedestal 410 is recessed to form a carrying area 411 for accommodating a plurality of carrier rings 420. A plurality of closed holes is opened in the bottom surface 413 of the carrying area 411, and an adsorber 440 is disposed in each hole. The adsorber 440 can adsorb and fix the carrier ring 420 onto the pedestal 410. The carrier ring 420 can be moved horizontally and vertically relative to the pedestal 410, and has a protruding carrying portion 422 disposed opposite to one side of the pedestal 410. The carrying portion 422 is used for carrying the substrate 450. As such, the carrier ring 420 employs the carrying portion 422 to carry and move the substrate 450 onto the pedestal 410 in the vapor deposition reaction chamber 400 for vapor deposition, and move the substrate 450 out of the reaction chamber after the reaction.

During the deposition, the product of the reaction is not only formed on the surface of the substrate 450 to form a deposition layer 430, but also forms a large amount of deposition residues 430a on the upper surface of the pedestal 410, the upper surface 421 of the carrier ring and between the carrier ring 420, the side surface 412 of the carrying area, and the bottom surface 413 of the carrying area. The deposition residues 430a on the side surface 412 of the carrying area and the bottom surface 413 of the carrying area are called edge cluster particles. The deposition residues 430a are formed along the gap between the carrier ring 420 and the side surface 412 of the carrying area. If the deposition residues fail to be fully removed, the deposition residues 430a will contaminate the reaction chamber 400 in the next vapor deposition process, and even may be deposited on the next substrate. If the substrate is a silicon chip for fabricating a super large-scale integrated circuit, the element property may be deteriorated and even short circuits may occur. The linear particles have a critical negative impact on the production yield of a semiconductor IC, so they must be cleaned thoroughly during the cleaning process.

FIGS. 2-4 are schematic sectional views of the flow of the cleaning process in the method for cleaning the vapor deposition reaction chamber commonly used in this field at present.

Referring to FIG. 2, after the substrate 450 is moved out of the vapor deposition reaction chamber 400, the carrier ring 420 returns to the carrying area 411 of the pedestal 410. During the cleaning process, first, the pedestal 410 and the carrier ring 420 are cleaned with a high pressure gas 455, in which the cleaning gas in the high pressure gas 455 and the deposition residues 430a react with each other to rapidly clear away deposition residues 430a on the upper surfaces of the pedestal 410 and the carrier ring 420. Thereafter, referring to FIG. 3, a second cleaning is performed with a low pressure gas 460. Finally, referring to FIG. 4, a full flush 470 is performed in the vapor deposition reaction chamber with a gas to end the cleaning process.

However, in the above clean method, the cleaning gas has a limited contact area with the deposition residues 430a, with a result that the deposition residues 430a between the carrier ring 420 and the side surface 412 of the carrying area, and between the carrier ring 420 and the bottom surface 413 of the carrying area cannot be fully removed. As shown in FIG. 5, a schematic view of the cleaning effect after the cleaning process in the prior art is shown. When the next vapor deposition process starts after the cleaning process, the bottom surface 413 of the carrying area on the pedestal 410 still has the deposition residues 430a remained thereon.

In view of the above, it is really necessary to provide a clean method for vapor deposition that avoids remaining any deposition residues after the vapor deposition reaction chamber is cleaned by a conventional clean method and overcomes the disadvantage of being unable to fully clean the gap between the carrier ring and the pedestal in the conventional clean method.

### SUMMARY OF THE INVENTION

The present invention provides a clean method for cleaning deposition residues in a gap between a pedestal and a carrier ring.

The clean method provided by the present invention is suitable for cleaning a vapor deposition reaction chamber having a pedestal and a carrier ring. The pedestal is used for carrying a substrate and the carrier ring is located on the surface of the pedestal for carrying or moving the substrate. The method includes separating the pedestal and the carrier ring, then cleaning the pedestal, the carrier ring, and an area lay between the pedestal and the carrier ring with a first gas, and afterward, a full flush is performed to clean the pedestal and the carrier ring.

According to an embodiment of the present invention, in the clean method, the carrier ring is moved vertically and spaced from the pedestal by a certain distance.

According to an embodiment of the present invention, in the clean method, the carrier ring is moved horizontally and spaced from the pedestal by a certain distance.

According to an embodiment of the present invention, in the clean method, the carrier ring is moved vertically and horizontally at the same time, and spaced from the pedestal by a certain distance.

According to an embodiment of the present invention, the clean method further includes cleaning the surfaces of the pedestal and the carrier ring with a second gas before the step of separating the pedestal and the carrier ring.

According to an embodiment of the present invention, in the clean method, the second gas is a high pressure gas and the first gas is a low pressure gas.

According to an embodiment of the present invention, in the clean method, the edge of the pedestal is recessed to form a carrying area for accommodating the carrier ring.

According to an embodiment of the present invention, in the clean method, the carrier ring has a protruding carrying portion disposed opposite to one side of the pedestal.

According to an embodiment of the present invention, in the clean method, the substrate includes a silicon chip, a glass substrate, a flexible plastic substrate, or other materials.

According to an embodiment of the present invention, the clean method is suitable for being carried out after a vapor deposition process is performed in the vapor deposition reaction chamber.

According to an embodiment of the present invention, the above clean method is suitable for being carried out before a vapor deposition process is performed in the vapor deposition reaction chamber.

According to an embodiment of the present invention, in the above clean method, the vapor deposition reaction chamber is a CVD reaction chamber.

In the clean method for vapor deposition provided by the present invention, the pedestal and the carrier ring are separated to make the low pressure gas and the cleaning gas fully contact the deposition residues between the pedestal and the carrier ring and then react with them. Therefore, if the vapor deposition reaction chamber is cleaned by using the clean method, the deposition residues remained in the gap between the pedestal and the carrier ring can be removed thoroughly, thereby preventing the residual particles from affecting the next vapor deposition process and enhancing the production yield of the vapor deposition and the element performance.

In order to make the aforementioned and other objectives, features, and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a vapor deposition process in the prior art.

FIGS. 2-4 are sectional views of the flow charts of the cleaning process in the prior art.

FIG. 5 is a schematic view of the cleaning effect after the cleaning process.

FIG. 6 is a schematic sectional view of a vapor deposition process according to an embodiment of the present invention.

FIGS. 7-9 are sectional views of the flow of the cleaning process according to an embodiment of the present invention.

FIG. 10 is a schematic sectional view of the cleaning effect after the cleaning process of the present invention.

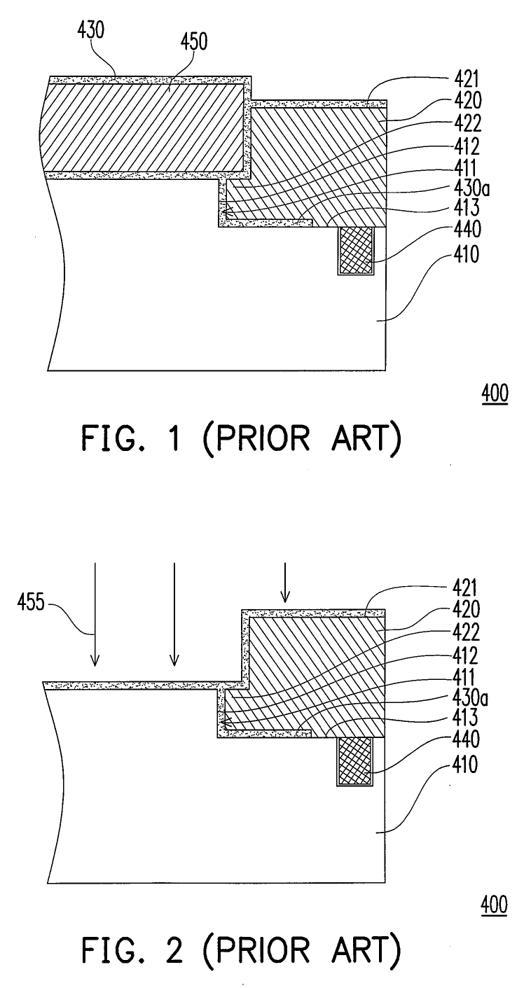

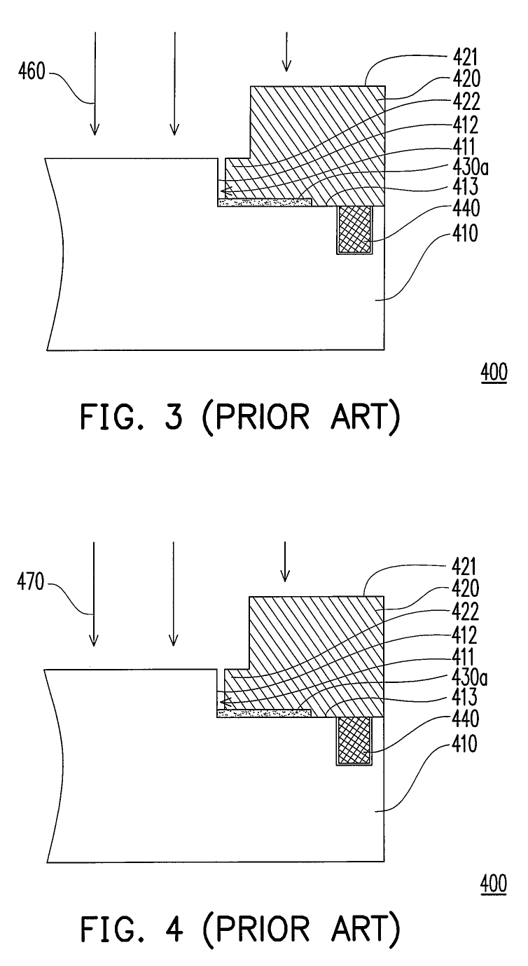

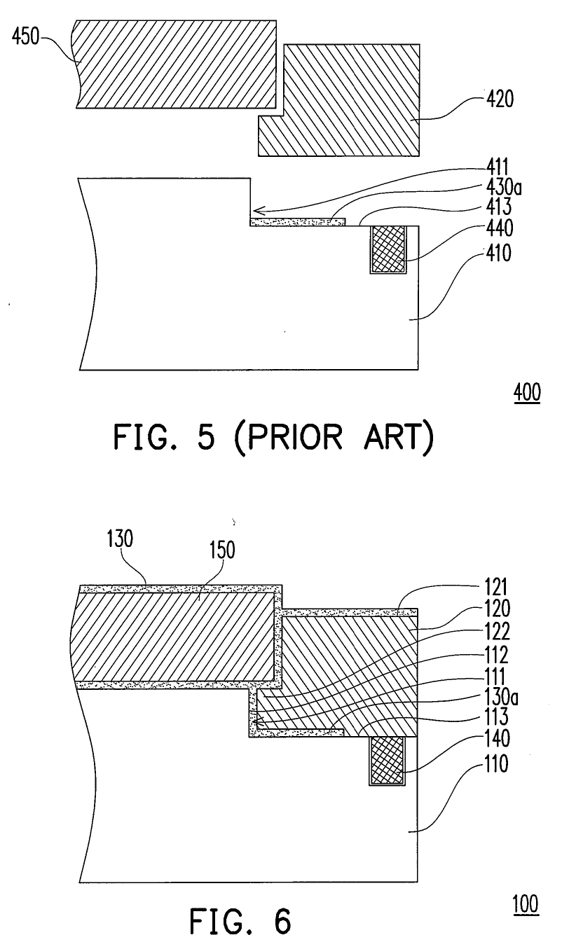

### DESCRIPTION OF EMBODIMENTS

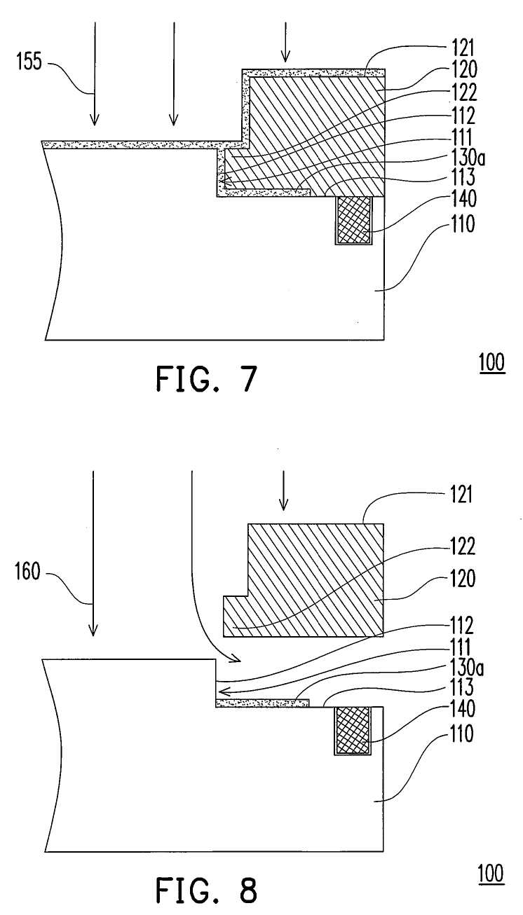

FIG. 6 is a schematic sectional view of a vapor deposition process. FIGS. 7-9 are schematic sectional views of the flow the cleaning process according to an embodiment of the present invention.

Referring to FIG. 6, during the deposition, a substrate 150 is disposed on a pedestal 110 in a vapor deposition reaction chamber 100. The substrate 150 can be a silicon chip, a glass substrate, a flexible plastic substrate, or other materials. The vapor deposition reaction chamber 100 is, for example, a CVD reaction chamber. The pedestal 110 is disposed in the vapor deposition reaction chamber 100 and the edge of the pedestal 110 is recessed to form a carrying area 111 for accommodating a plurality of carrier rings 120. A plurality of closed holes is opened in the bottom surface 113 of the carrying area 111, and an adsorber 140 is disposed in each hole. The adsorber 140 can adsorb and fix the carrier ring 120 onto the pedestal 110. The carrier ring 120 can be moved horizontally and vertically relative to the pedestal 110, and has a protruding carrying portion 122 disposed opposite to one side of the pedestal 110. The carrying portion 122 is used for carrying the substrate 150 for the vapor deposition. As such, the carrier ring 120 employs the carrying portion 122 to carry and move the substrate 150 onto the pedestal 110 in the vapor deposition reaction chamber 100 for vapor deposition, and move the substrate 150 out of the vapor deposition reaction chamber 100 after the reaction. The material deposited in the vapor deposition is, for example, an insulating layer, such as silicon nitride, silicon oxynitride, or silicon oxide.

During the deposition, the product of reaction is not only deposited on the surface of the substrate 150 to form a deposition layer 130, but also forms a large amount of deposition residues 130a on the upper surface of the pedestal 110, the upper surface 121 of the carrier ring, and between the carrier ring 120, the side surface 112 of the carrying area, and the bottom surface 113 of the carrying area. The deposition residues 130a are formed along the gap between the carrier ring 120 and the side surface 112 of the carrying area.

Referring to FIG. 7, after the vapor deposition step, the substrate 150 is moved out of the vapor deposition reaction chamber 100, and the carrier ring 120 returns to the carrying area 111 of the substrate 110. Then, the cleaning process of the vapor deposition reaction chamber 100 begins. First, the pedestal 110 and the carrier ring 120 are cleaned with a high pressure gas 155, in which a cleaning gas in the high pressure gas 155 and the deposition residues 130a react with each other to rapidly clear away the deposition residues 130a on the upper surfaces of the pedestal 110 and the carrier ring 120. The cleaning gas in the high pressure gas 155 is usually NF₃ or F₂, for example.

Referring to FIG. 8, after being cleaned by the high pressure gas 155, the carrier ring 120 is vertically moved upward to above the carrying area 111 of the pedestal 110 and spaced from the pedestal 110 by a certain space. After that, a second cleaning is performed with a low pressure gas 160. A cleaning gas in the low pressure gas 160 may enter the carrying area 111 along the space between the carrier ring 120 and the carrying area 111, and then fully contact the deposition residues 130a on the bottom surface 113 of the carrying area to react with them, so as to clear away the deposition residues 130a. The cleaning gas in the low pressure gas 160 is usually NF₃ or F₂, for example.

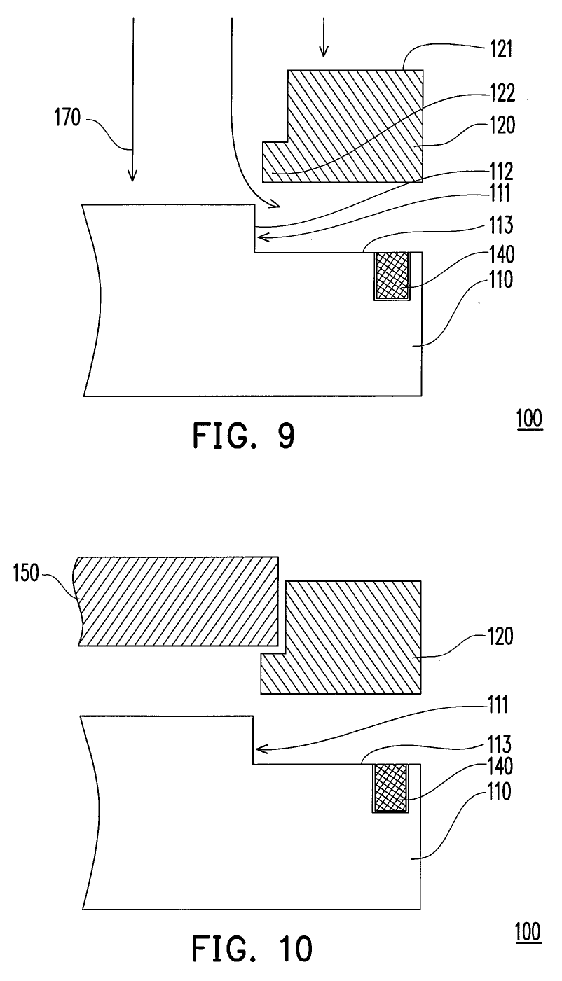

Referring to FIG. 9, after being cleaned by the low pressure gas 160, nearly no deposition residues 130a are remained on the surfaces of the pedestal 110 and the carrier ring 120. At this time, a full flush 170 is performed in the vapor deposition reaction chamber with a cleaning gas, such that the cleaning gas fully contacts each of the surfaces of the pedestal 110 and the carrier ring 120, and then the cleaning process is finished.

As shown in FIG. 10, a schematic view of the cleaning effect after the cleaning process in the present invention is shown. Before the next vapor deposition reaction, each of the surfaces of the pedestal 110 and the carrier ring 120 is cleaned thoroughly without any remained sediments.

In the above embodiment, before being cleaned by the low pressure gas 160, the carrier ring 120 is vertically moved upward to above the carrying area 111 of the pedestal 110 and spaced from the carrying area 111 of the pedestal 110 by a certain space. In this manner, the cleaning gas fully contacts the deposition residues 130a on the bottom surface 113 of the carrying area to react with them, so as to clear away the deposition residues 130a. However, the carrier ring 120 may also be moved horizontally and spaced from the pedestal 110 by a certain space. Alternatively, the carrier ring 120 can also be moved vertically and horizontally at the same time to be far way from the pedestal 110, and spaced from the pedestal 110 by a certain distance. The pedestal 110 may also be moved to be spaced from the carrier ring 120 by a certain space.

In addition, the above embodiment is illustrated with a reaction chamber in a CVD process. However, the present invention is not limited thereby. The present invention can be used to clean deposition residues remained between the carrier ring for carrying/moving the substrate or other members and the pedestal in the reaction chamber after other vapor deposition processes, or ensure that the reaction chamber has been cleaned thoroughly before the deposition process.

If the vapor deposition reaction chamber is cleaned by using the clean method provided by the present invention, the deposition residues remained in the gap between the pedestal and the carrier ring can be removed thoroughly, thereby preventing the residual particles from affecting the next vapor deposition process and enhancing the production yield of the vapor deposition reaction and the element performance.

Though the present invention has been disclosed above through the preferred embodiment, the preferred embodiment is not intended to limit the present invention. Anyone skilled in the art can make some modifications and variations without departing from the spirit and scope of the present invention. Therefore, the protecting scope of the present invention falls in the appended claims.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A clean method, for cleaning a vapor deposition reaction chamber having a pedestal and a carrier ring, wherein the pedestal is used for carrying a substrate and the carrier ring is located on the surface of the pedestal for carrying or moving the substrate, the method comprising:
separating the pedestal and the carrier ring;
cleaning the pedestal, the carrier ring, and an area lay between the pedestal and the carrier ring with a first gas; and
performing a full flush to clean the pedestal and the carrier ring.

2. The clean method as claimed in claim 1, wherein the carrier ring is moved vertically and spaced from the pedestal by a certain distance.

3. The clean method as claimed in claim 1, wherein the carrier ring is moved horizontally and spaced from the pedestal by a certain distance.

4. The clean method as claimed in claim 1, wherein the carrier ring is moved vertically and horizontally at the same time and spaced from the pedestal by a certain distance.

5. The clean method as claimed in claim 1, further comprising cleaning the surfaces of the pedestal and the carrier ring with a second gas before the step of separating the pedestal and the carrier ring.

6. The clean method as claimed in claim 5, wherein the second gas is a high pressure gas and the first gas is a low pressure gas.

7. The clean method as claimed in claim 1, wherein the edge of the pedestal is recessed to form a carrying area for accommodating the carrier ring.

8. The clean method as claimed in claim 1, wherein the carrier ring has a protruding carrying portion disposed opposite to one side of the pedestal.

9. The clean method as claimed in claim 1, wherein the substrate comprises a silicon chip, a glass substrate, a flexible plastic substrate, or other materials.

10. The clean method as claimed in claim 1, suitable for being carried out after a vapor deposition process is performed in the vapor deposition reaction chamber.

11. The clean method as claimed in claim 1, suitable for being carried out before a vapor deposition process is performed in the vapor deposition reaction chamber.

12. The clean method as claimed in claim 1, wherein the vapor deposition reaction chamber is a chemical vapor deposition (CVD) reaction chamber.
